(19) United States
(12) Patent Application Publication
(10) Pub. No.: US 2017/0059984 A1
(43) Pub. Date: Mar. 2, 2017

(54) PHOTOMASK CLEANING APPARATUS, METHOD OF CLEANING A PHOTOMASK, AND METHOD OF MANUFACTURING A SEMICONDUCTOR DEVICE

(71) Applicant: Samsung Electronics Co., Ltd., Suwon-si (KR)

(72) Inventors: Jin-su KIM, Hwaseong-si (KR); Jae-hyuck CHOI, Seoul (KR); Byung-gook KIM, Seoul (KR); Soo-wan KOH, Hwaseong-si (KR)

(21) Appl. No.: 15/210,872

(22) Filed: Jul. 14, 2016

(30) Foreign Application Priority Data
Aug. 27, 2015 (KR) 10-2015-0121036

(51) Int. Cl. G03F 1/82; G03F 7/20; B08B 7/00

(52) U.S. Cl. CPC G03F 1/82; B08B 7/0042; G03F 7/20

(57) ABSTRACT

Disclosed is a method. The method includes placing a photomask on a receiver of a cleaning apparatus, removing adhesive residue from the photomask by irradiating laser on the adhesive residue, attaching a pellicle to the photomask, and exposing a semiconductor substrate to a light using the photomask, wherein the irradiating laser repeatedly pauses and restarts during the removing of the adhesive residue.

### CROSS-REFERENCE TO RELATED APPLICATION

This application claims the benefit of priority under 35 U.S.C. §119 to Korean Patent Application No. 10-2015-0121036, filed on Aug. 27, 2015, in the Korean Intellectual Property Office, the disclosure of which is incorporated herein by reference in its entirety.

### BACKGROUND

The disclosed embodiments relate to a photomask cleaning apparatus, for example, to a photomask cleaning apparatus which effectively removes a residual material of a pellicle adhesive remaining on a surface of a photomask.

A photo process may be used to form a certain pattern on a semiconductor substrate. For example, a photoresist pattern may be formed by transferring a pattern, formed on a photomask, onto a photoresist layer disposed on a semiconductor substrate. A certain pattern may be formed by etching the semiconductor substrate or a material layer disposed on the semiconductor substrate by using the photoresist pattern as an etching mask. The photomask is a mask used to form the photoresist pattern on the semiconductor substrate and may be generally formed by forming a pattern including a light blocking material on a light transmitting substrate. A light blocking pattern image of the photomask may be transferred onto a photoresist disposed on the semiconductor substrate by exposing the photoresist with a patterned light by using the photomask where a light blocking pattern is formed. In this case, a pellicle for protecting the light blocking pattern may be formed to prevent a foreign material from being adsorbed into or attached onto the light blocking pattern formed on the photomask. An adhesive may be used for fixing the pellicle to the photomask. For example, the pellicle may be adhered to the photomask by the adhesive.

### SUMMARY

Aspects of the inventive concept provide a photomask cleaning apparatus for minimizing damage of a photomask.

Aspects of the inventive concept are not limited to the aforesaid, but other aspects not described herein will be clearly understood by those of ordinary skill in the art from descriptions below.

According to an aspect of the inventive concept, a method comprises placing a photomask on a receiver of a cleaning apparatus, and removing adhesive residue from the photomask by irradiating laser on the adhesive residue, wherein the irradiating laser repeatedly pauses and restarts during the removing of the adhesive residue.

According to an embodiment of the disclosure, a method comprises removing a pellicle from a photomask, the photomask comprising a first region where a mask pattern is formed and a second region surrounding the first region, placing the photomask on a receiver of a cleaning apparatus, and removing pellicle adhesive residue from the photomask by irradiating laser on the adhesive residue, wherein the laser has a tophat profile, and the irradiating laser removes the pellicle adhesive residue in the second region of the photomask.

According to an embodiment of the disclosure, a method comprises placing a photomask on a receiver of a cleaning apparatus, removing adhesive residue from the photomask by irradiating laser on the adhesive residue, attaching a pellicle to the photomask, and exposing a semiconductor substrate to a light using the photomask, wherein the irradiating laser repeatedly pauses and restarts during the removing of the adhesive residue.

### BRIEF DESCRIPTION OF THE DRAWINGS

Example embodiments of the inventive concept will be more clearly understood from the following detailed description taken in conjunction with the accompanying drawings in which:

FIG. 1 is a diagram schematically illustrating a pellicle adhered to a photomask according to an example embodiment;

FIG. 2 is a diagram for describing an adhesive residual material formed on a photomask according to an example embodiment;

FIG. 3 is a diagram for describing a photomask cleaning apparatus according to an example embodiment;

FIG. 4 is a block diagram illustrating elements of a photomask cleaning apparatus according to an example embodiment;

FIG. 5 is a flowchart illustrating a photomask cleaning method using a photomask cleaning apparatus according to an example embodiment;

FIG. 6 is a graph showing an energy change caused by irradiation of a laser applied to a photomask cleaning apparatus according to an example embodiment;

FIG. 7 is a graph showing an energy change caused by various kinds of laser applied to a photomask cleaning apparatus according to an example embodiment; and

FIG. 8 shows various images of photomasks cleaned by a photomask cleaning apparatus according to an example embodiment.

### DETAILED DESCRIPTION

As used herein, the term “and/or” includes any and all combinations of one or more of the associated listed items. Expressions such as “at least one of” when preceding a list of elements, modify the entire list of elements and do not modify the individual elements of the list.

Example embodiments of the inventive concept will be described below in more detail with reference to the accompanying drawings. The inventive concept may, however, be embodied in different forms and should not be construed as limited to the embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention. It should be noted that elements shown in the accompanying drawings may be scaled up or down for convenience in description. The dimensions of respective elements may be exaggerated or reduced.

It will also be understood that when an element is referred to as being ‘on’ another element, it can be directly on the other element, or intervening elements may also be present. Further, it will be understood that when an element is referred to as being ‘under’ another element, it can be directly under, and one or more intervening elements may also be present. In addition, it will also be understood that when an element is referred to as being ‘between’ two elements, it can be the only element between the two elements, or one or more intervening elements may also be present. Other terms for describing a relationship between elements, for example, “between” and “directly between” may be understood likewise. However, the term “contact,” as used herein refers to a direct connection (i.e., touching) unless the context indicates otherwise.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

In the following description, the technical terms are used for explaining specific exemplary embodiments, while not limiting the present embodiments. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly.

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, memory card, hard drive including additional components, or a mobile phone, laptop, tablet, desktop, camera, or other consumer electronic device, etc.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein. Hereinafter, exemplary embodiments will be described in detail with reference to the accompanying drawings.

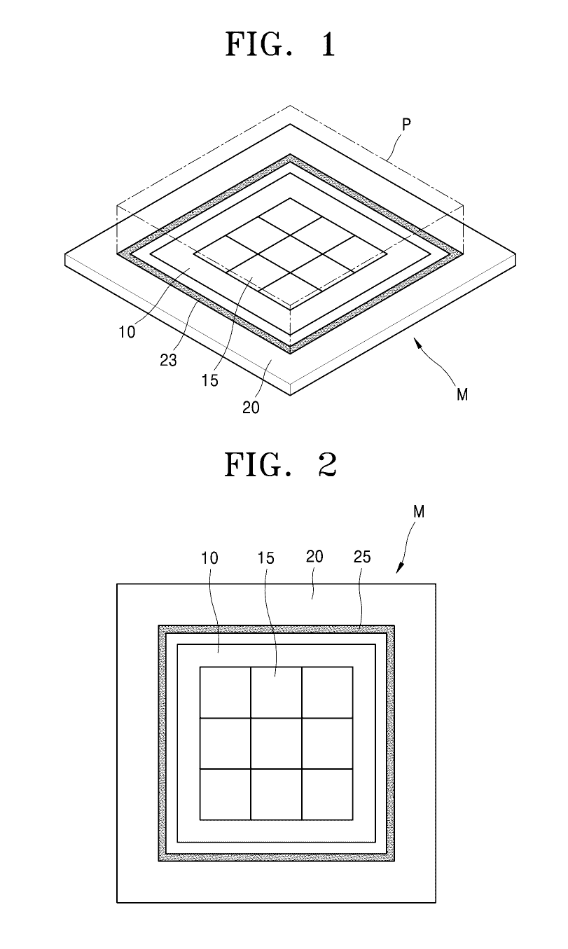

FIG. 1 is a diagram schematically illustrating a pellicle P adhered to a photomask M according to an example embodiment.

Referring to FIG. 1, the photomask M may include a first region 10, where a pattern 15 is formed, and a second region 20, which is disposed outside the first region 10 and to which the pellicle is adhered.

A photo lithography process may be used to form a certain pattern on a semiconductor substrate. For example, a photoresist pattern may be formed by transferring a pattern 15 of the photomask M onto a photoresist layer disposed on the semiconductor substrate. A certain pattern may be formed by etching the semiconductor substrate or a material layer disposed on the semiconductor substrate by using the photoresist pattern.

The photomask M may be a mask used to form the photoresist pattern on the semiconductor substrate and may be generally formed by forming the pattern 15 including a light blocking material on a light transmitting substrate. An image of the pattern 15 may be transferred onto a photoresist disposed on the semiconductor substrate by exposing the photoresist to a light pattern by using the photomask M where the pattern 15 is formed.

In some embodiments, the pellicle P may be formed on the pattern 15 to protect the pattern 15. The pellicle P may be formed on the pattern 15 to prevent a foreign material from being attached onto and/or absorbed into the pattern 15. For example, the pellicle P may prevent a situation where the pattern 15 is not properly transferred onto the photoresist due to a foreign material or a pollutant adsorbed into and/or attached onto the pattern 15 formed on the photomask M. An adhesive 23 may be used to fix the pellicle P to the photomask M. For example, the pellicle P may be adhered to the second region 20 of the photomask M by the adhesive 23.

The photomask M may include a substrate. The substrate may include, for example, quartz (Qz) or a metal-based material. For example, the metal-based material may be one material of fused silica, quartz (Qz), chromium (Cr), molybdenum (Mo), silicon (Si), molybdenum silicon oxynitride (MoSiON), chromium nitride (CrN), tantalum (Ta), boron (B), tantalum boron nitride (TaBN), tellurium (Te), tantalum tellurium (TaTe), and ruthenium (Ru).

The adhesive 23 may be a polymer-based material. For example, in some embodiments, the adhesive 23 may include one material of the following: fluoropolymer, polyurethane, acryl, epoxy, silicon, ethylene, butylene, and styrene block copolymer.

FIG. 2 is a diagram for describing an adhesive residual material 25 formed on a photomask M according to an example embodiment.

Referring to FIG. 2, the photomask M may include a first region 10 and a second region 20. The first region 10 may be a central region of the photomask M, and may be a region where a certain pattern 15 is disposed. The second region 20 may be an outer region of the photomask M, and may be a region which is disposed on a circumference of the first region 10 and to which a pellicle P (see FIG. 1) is adhered. For example, the first region 10 may be a center region of the photomask M, and the second region 20 may be the periphery region surrounding the center region 10.

For example, the second region 20 may denote a region where the adhesive residual material 25 is disposed. The residual material 25 may be removed in a process of cleaning the photomask M according to an exemplary embodiment of the disclosure.

As described above, the pellicle P (see FIG. 1) may be adhered to the second region 20 of the photomask M by a certain adhesive 23 (see FIG. 1). The pellicle P may prevent the pattern 15 formed on the photomask M from being polluted.

The pellicle P may be removed from the photomask M periodically, and the photomask M may be cleaned subsequently. For example, an operation of replacing the pellicle P (see FIG. 1) may be performed periodically to clean the photomask M. After the pellicle P (see FIG. 1) is removed from the photomask M, the adhesive residual material 25 may remain in the second region 20 of the photomask M. FIG. 2 illustrates a case where the adhesive residual material 25 remains in a tetragonal shape. However, the present embodiment is not limited thereto. In other exemplary embodiments, the adhesive residual material 25 may remain in only a portion of the second region 20. After the pellicle P (see FIG. 1) is removed, the adhesive residual material 25 remaining on the photomask M may be removed, and a new pellicle may be applied to the photomask M.

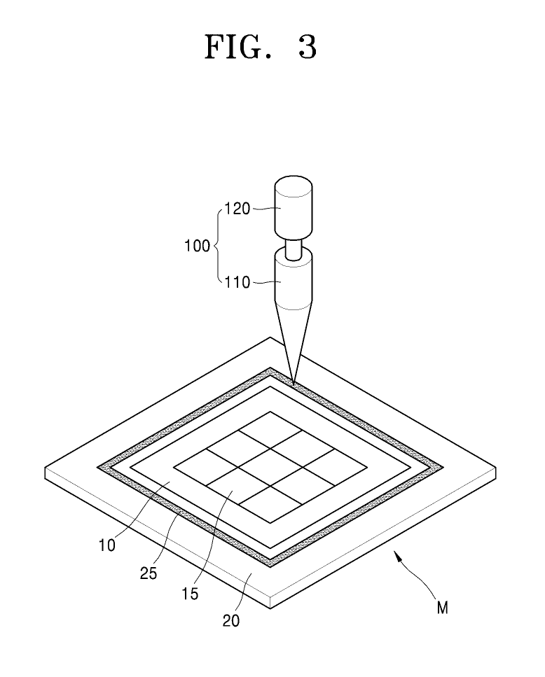

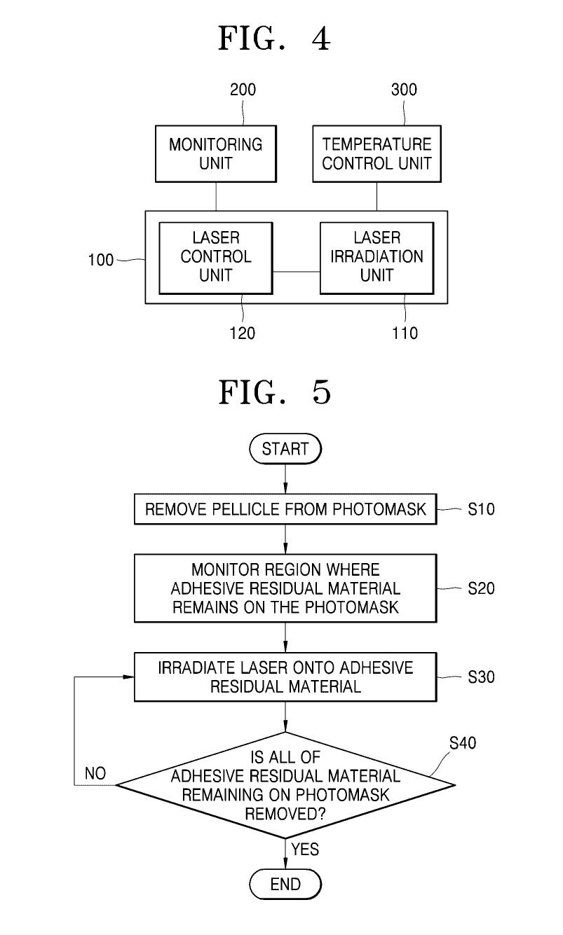

FIG. 3 is a diagram for describing a photomask cleaning apparatus 100 according to an example embodiment.

Referring to FIG. 3, the photomask cleaning apparatus 100 according to an example embodiment may include a laser irradiation unit 110 and a laser control unit 120. Also, the photomask cleaning apparatus 100 may further include a monitoring unit 200 (see FIG. 4) and a temperature control unit 300 (see FIG. 4).

The laser irradiation unit 110 may irradiate a laser L to remove the adhesive residual material 25 remaining in the second region 20 of the photomask M. The laser L may have a wavelength having a range, for example, of about 193 nm to about 355 nm.

For example, the photomask M may include a Cr substrate, and when the laser L has a wavelength of 193 nm or less, a reflectance of the laser L with respect to Cr is rapidly reduced, causing damage on the surface of the photomask M. On the other hand, when the laser L has a wavelength of more than 355 nm, a thermal removal process may be performed, and the photomask M is heated by an irradiating laser L. Thus the adhesive residual material 25 is liquefied or gasified and the adhesive residual material 25 may be removed by a thermal removal process instead of a physical removal process. The laser L may be directly irradiated onto the adhesive residual material 25 in a physical removal process. For this reason, the photomask M may be damaged by a thermal energy.

Therefore, the laser irradiation unit 110 of the photomask cleaning apparatus 100 according to example embodiments may irradiate the laser L having a wavelength ranging from about 193 nm to about 355 nm.

In some embodiments, in order to minimize damage of the photomask M, the laser L may use a nano second pulse laser. For example, the laser L may be irradiated for several nanoseconds (ns) to tens of nanoseconds (ns). For example, the laser L having a pulse duration of about 1 ns to about 50 ns may be used. The nano second pulse laser may be irradiated to the residual material 25 a plurality of times.

When the pulse duration increases to several micro seconds or longer, thermal conduction to the adhesive residual material 25 may increase, and the ability to control a cleaning process may be reduced, causing an increase in a possibility that a thermal damage of the photomask M occurs. A wavelength range and a pulse duration of the laser L irradiated by the laser irradiation unit 110 may depend on the kind of the adhesive residual material 25 which is to be removed.

A method of soaking a photomask into a sulphuric acid bath may be applied to remove an adhesive residual material or a method of rotating a photomask while injecting sulphuric acid may be applied to remove an adhesive residual material. As described above, in a case of using sulphuric acid, residual pollution is inevitably caused by a sulphate, and for this reason, a photomask and a photomask pattern are easily damaged. For example, sulphuric acid makes sulphate, and sulphate may be attached on the mask substrate (including the first region 10 and the second region 20) and/or on the mask pattern. The mask substrate may be damaged when the sulphate is removed by a photomask cleaning apparatus.

On the other hand, according to some exemplary embodiments, the photomask cleaning apparatus 100 may remove all of the adhesive residual material 25 by using the laser L without using a separate cleaning solution, thereby preventing the photomask M from being damaged by a cleaning solution, for example, sulphuric acid.

For example, the photomask cleaning apparatus 100 according to an example embodiment may remove the adhesive residual material 25 by using the laser L without undergoing a separate wet cleaning process. Therefore, damage of the photomask M is minimized, and the photomask M is cleaned.

When the laser L is irradiated onto the photomask M for a long time, energy may be accumulated in the photomask M, and the photomask M may be damaged by the accumulated energy. Therefore, the present embodiment proposes the photomask cleaning apparatus 100 that adjusts a period or cycle, a frequency, a wavelength, an irradiation duration, the number of repetitions, and a repetition interval of the laser L and thus removes only the adhesive residual material 25 without the photomask M being damaged.

FIG. 4 is a block diagram illustrating elements of a photomask cleaning apparatus 100 according to an example embodiment.

Referring to FIGS. 3 and 4, the photomask cleaning apparatus 100 according to an example embodiment may include a laser irradiation unit 110 and a laser control unit 120. Also, the photomask cleaning apparatus 100 may further include a monitoring unit 200 and a temperature control unit 300. For example, as shown in FIG. 4, a monitoring unit 200 and a temperature control unit 300 may be connected to a photomask cleaning apparatus 100. In certain embodiments, a monitoring unit 200 and a temperature 300 may be included in a photomask cleaning apparatus 100 (not shown).

The laser irradiation unit 110 may irradiate a laser L onto the adhesive residual material 25 disposed on the photomask M. The adhesive residual material 25 may be caused by the adhesive 23 (see FIG. 1) which is used for the pellicle P (see FIG. 1) to be adhered to the photomask M.

The laser irradiation unit 110 may be, for example, an infrared wavelength laser irradiation device supplying a laser L having an infrared wavelength. However, the laser irradiation unit 110 is not limited to an infrared wavelength laser irradiation unit. In certain example embodiments, the laser irradiation unit 110 may be an ultraviolet wavelength laser irradiation unit. The laser L may be selected based on the kind of the photomask M and the kind of the adhesive residual material 25.

The laser irradiation unit 110 may include a laser source that emits a laser, an expander that expands the laser emitted from the laser source, a beam parallel unit that converts the laser, expanded by the expander, into a parallel laser, a light path change unit that changes a light path of the parallel laser to a desired direction, and an output coupler that allows the laser, whose the light path has been changed by the light path change unit, to be irradiated onto a target. However, this is merely an example. Various types of laser irradiation units 110 may be provided by those of ordinary skill in the art. The various units described herein may be formed using various physical and electrical components.

The laser control unit 120 may control an operation of the laser irradiation unit 110. For example, the laser control unit 120 may include an output setting unit that sets an output of a laser, a repetition frequency setting unit that sets a repetition period (for example, a pulse interval) of an irradiation pulse of the laser, a wavelength setting unit that sets a wavelength of the laser, and a pulse width setting unit that sets a width of the pulse. However, this is merely an example. Various types of laser control units 120 may be provided by those of ordinary skill in the art. The control unit 120 may be implemented using hardware and software, such as various circuits, and computer program code configured to control the operation of the laser irradiation unit 110.

The laser control unit 120 may control one or more of a period, a frequency, a wavelength, an irradiation duration, the number of repetitions, and a repetition interval of the laser L. The laser L may be controlled depending on the kind of the photomask M and the kind of the adhesive residual material 25.

The laser control unit 120 may control the laser irradiation unit 110 to irradiate a tophat beam. The tophat beam may be a beam that enables energy of a laser to have a uniform energy density in a whole laser irradiation region. The tophat beam may be generated from a Gaussian beam by a plurality of diffractive optical elements. For example, the photomask cleaning apparatus 100 may include at least one diffractive optical element converting a Gaussian laser beam to a tophat laser beam.

The monitoring unit 200 may scan the photomask M by using a scanner. The monitoring unit 200, for example, may include a function of generating a map. For example, the monitoring unit 200 may generate a map corresponding to the area where adhesive residual material 25 remains on the photomask M, based on an image obtained though scanning by the scanner. As described above, when the map corresponding to the adhesive residual material 25 is generated, the laser irradiation unit 110 may remove the adhesive residual material 25 by minimally moving. For example, when a map for the residual material 25 is generated and used for the residual material removal process, the removal process will be fast and efficient. Therefore, a total working time for cleaning the photomask M is shortened. Also, the monitoring unit 200 may monitor the photomask M in real time. The monitoring unit 200 may check information about the adhesive residual material 25 in real time, thereby increasing the cleaning efficiency and shortening the cleaning time of the photomask M. The monitoring unit 200 may be implemented using hardware and software, such as various circuits, and computer program code configured to control the scanning of the photomask M.

The temperature control unit 300 may heat the photomask M up to a certain temperature before irradiating the laser L onto the photomask M, thereby easily removing the adhesive residual material 25. Also, after the adhesive residual material 25 is completely removed, the temperature control unit 300 may cool down the photomask M to a certain temperature to prevent the photomask M from being deformed. The temperature control unit 300 may include components such as a heating element, various circuits such as control circuitry, and in some cases control software for heating the photomask M.

FIG. 5 is a flowchart illustrating a photomask cleaning method using a photomask cleaning apparatus according to an example embodiment.

Referring to FIGS. 3 to 5, the photomask cleaning method may include the following steps according to an example embodiment. In some embodiments, the cleaning may be performed in the following order. In certain embodiments, the cleaning may be performed in another order. In operation S10, the pellicle P (see FIG. 1) may be removed from the photomask M. After the pellicle P (see FIG. 1) is removed. In operation S20, the monitoring unit 200 may scan the photomask M to generate a map showing one or more regions where the adhesive residual material 25 remains. In operation S30, the laser irradiation unit 110 may irradiate the laser L onto a region where the adhesive residual material 25 remains. The laser control unit 120 may control the laser irradiation unit 110 to irradiate the laser L in the region where the adhesive residual material 25 remains by using the information on the map. The laser irradiation unit 110 may pause on the irradiation of the laser L before the irradiation energy of the laser L reaches an energy level that substantially damages the photomask M. The laser irradiation unit 110 may irradiate the laser L again after the photomask M discharges all or most of the energy absorbed by the photomask M of the irradiation of the laser L, thereby removing the adhesive residual material 25. For example, by repeating pausing on and re-radiating the laser L a plurality of times, the adhesive residual material 25 may be removed from the particular region. In some embodiments, the laser irradiation unit 110 may irradiate a tophat beam. In operation 40, after the irradiation of the laser L onto a region where the adhesive residual material 25 remains is completed, the monitoring unit 200 may determine whether all of the adhesive residual material 25 is removed from the photomask M (e.g., from any additional regions). When the adhesive residual material 25 remains on the photomask M, the adhesive residual material 25 may be removed from another region by again irradiating the laser L onto the region where the adhesive residual material 25 remains. When all of the adhesive residual material 25 is removed, a photomask cleaning process may end.

For example, although not shown in the flowchart, after the pellicle P (see FIG. 1) is removed from the photomask M in operation S20, the temperature control unit 300 may heat the photomask M up to a certain temperature. Also, after all of the adhesive residual material 25 on the photomask M is removed in operation S40, the temperature control unit 300 may cool the photomask M down to a certain temperature.

In some embodiments, the method may also include placing the photomask to a receiver of the cleaning apparatus before monitoring the region where the adhesive residual material remains on the photomask. When the cleaning process is completed, a pellicle may be attached on the photomask for further use of the photomask for manufacturing a semiconductor device.

In certain embodiments, the method may include a step of manufacturing a semiconductor device. For example, the method may include coating a photoresist material layer on a semiconductor substrate. After cleaning the residue of the adhesive material, a pellicle may be attached on the photomask. Then the photomask may be used to expose a semiconductor substrate on which a photoresist layer is formed to manufacture a semiconductor device.

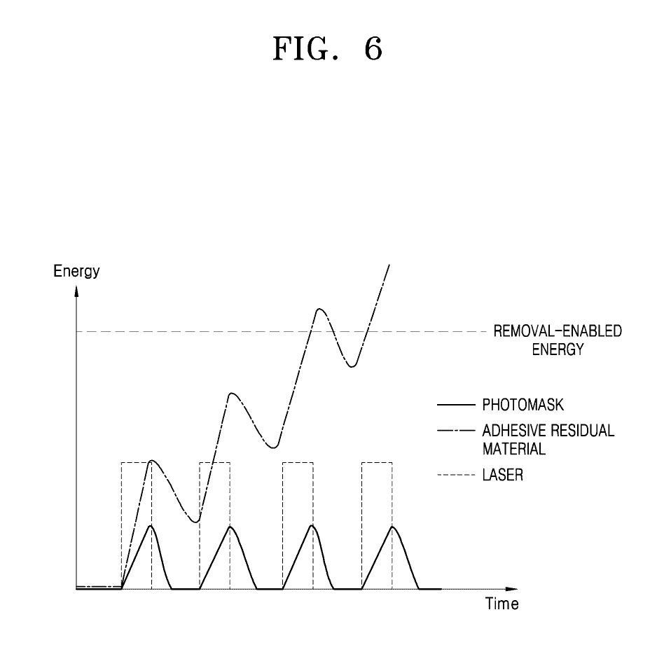

FIG. 6 is a graph showing an energy change accumulated in the mask and in the adhesive residual material by irradiation of a laser applied by a photomask cleaning apparatus according to an example embodiment.

Referring to FIGS. 3 and 6, the graph in FIG. 6 shows energy levels accumulated in the photomask M and the adhesive residual material 25. The graph shows the changes of the energy levels with respect to time. The laser L is irradiated onto the photomask M and the adhesive residual material 25. While the laser L is being irradiated onto the adhesive residual material 25 to remove the adhesive residual material 25, the laser L may be irradiated onto a periphery and a bottom of the adhesive residual material 25. Therefore, when the laser L is continuously irradiated for a certain time or more, the adhesive residual material 25 may be removed. However, the photomask M may be damaged by energy of the laser L. For example, the laser L may be irradiated onto the mask under the adhesive residual material 25, and the mask under the adhesive residual material 25 and near the periphery of the adhesive residual material 25 may be damaged by laser L.

As described above, the material forming the photomask M may be different from the material forming the adhesive residual material 25. The photomask M may be formed of quartz (Qz) or a metal-based material, and the adhesive residual material 25 may be formed of a polymer-based material. When irradiating the laser L, the level of energy applied to and accumulating on the photomask M may vary depending on the kind of material, and the time discharging the energy may also vary. For example, the energy accumulation rate and the energy discharge rate depend on the material on which the laser L is irradiated.

When the laser L is irradiated periodically (e.g., with a certain frequency) onto the adhesive residual material 25 (e.g., when the laser pointed at a same location, and which may be stationary, is repeatedly irradiated onto a same portion of the adhesive residual material 25), laser energy may be accumulated in the irradiated material (e.g., the mask M or the adhesive residual material 25) during the irradiating times, and may be dissipated from the irradiated material (e.g., the mask M or the adhesive residual material 25) between the irradiating times. The energy dissipation time may depend on material. The laser energy may be accumulated in the form of thermal energy, and the thermal energy may be dissipated by cooling down its carrying material (e.g., the mask M or the adhesive residual material 25). A dissipation time or a mitigating time in a polymer-based material may be longer than a dissipation time or mitigating time in a metal-based material. For example, during a time that the photomask M discharges all energy absorbed in the photomask M by the irradiation of the laser L, certain energy may still remain in the adhesive residual material 25.

By using a mitigation duration difference of energy accumulated by irradiation of the laser L between the photomask M and the adhesive residual material 25, the adhesive residual material 25 may be removed without the photomask M being damaged. For example, the laser irradiation unit 110 (see FIG. 4) may pause the irradiation of the laser L before the accumulated energy reaches a level that substantially damages the photomask M. During the pause, the photomask M discharges the accumulated laser energy. After the photomask M discharges energy (e.g., all or substantially all energy) which is absorbed during irradiation of the laser L, the laser irradiation unit 110 may again irradiate the laser L, thereby removing the adhesive residual material 25 without the photomask M being damaged.

Here, pausing and restarting the irradiation of the laser L allows the laser L to be irradiated onto the adhesive residual material 25 at certain intervals by the laser irradiation unit 110 (see FIG. 4). This is fulfilled by setting the laser L to have a certain frequency. The frequency of the laser L may be between about 1 Hz and about 200 Hz, and in this case, the period of the laser L may be about 0.005 sec to about 1 sec. A frequency of the laser L may be selected based on a mitigation duration of the energy in the photomask M and a mitigation duration of the energy in the adhesive residual material. For the laser L having a constant frequency, the mitigation duration of the energy in the adhesive residual material 25 may be longer than the mitigation duration of the energy in the photomask M. The interval pausing the irradiation may be set to be between a time that the mask M discharges substantially all laser energy accumulated in the mask M and a time that the residual adhesive material 25 discharges substantially all laser energy accumulated in the residual adhesive material 25. Because the discharge time in the mask M is shorter than the discharge time in the residual adhesive material 25, a repeating irradiation of the laser L may accumulate laser energy in the residual adhesive material 25 while laser energy may not be accumulated in the mask M any more.

For example, when the laser L having the constant frequency is irradiated onto the adhesive residual material 25 for enough time, accumulated energy may enable the adhesive residual material 25 to be removed. The removal-enabling energy may be about 1 mJ/cm² to about 200 mJ/cm², depending on the kind of the adhesive residual material 25.

The laser L may be adjusted by the laser control unit 120 (see FIG. 4) to have a wavelength of which absorption rate is higher in the adhesive residual material 25 than the photomask M. For example, the laser control unit 120 may select a laser L having a wavelength range of which absorption rate is higher in a polymer-based material than a metal-based material. The wavelength may be changed depending on a material of the photomask M and a material of the adhesive 23 (see FIG. 1).

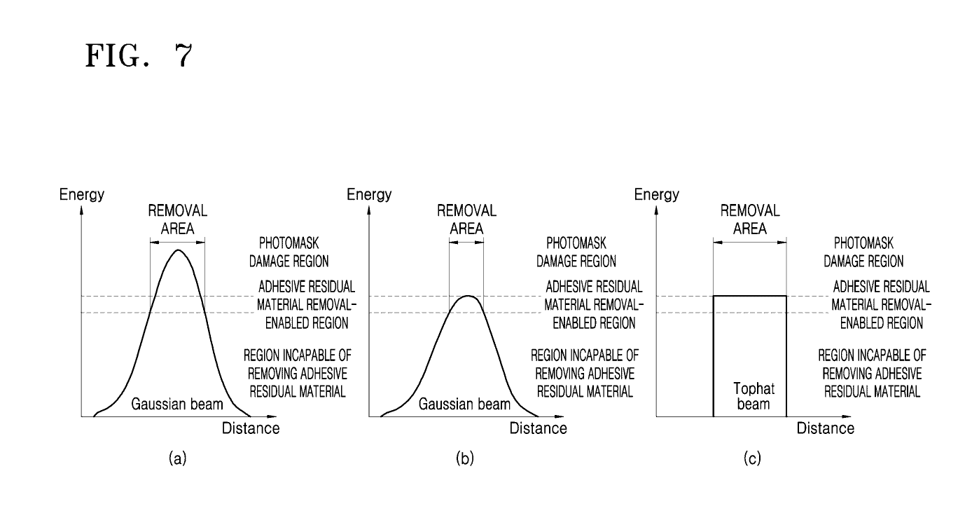

FIG. 7 is a graph showing energy profiles according to the kind of a laser applied to a photomask cleaning apparatus according to an example embodiment.

Referring to FIGS. 3 and 7, the graph shows removal areas of the adhesive residual material 25 according to the kind of the laser L used. FIGS. 7A and 7B show graphs when Gaussian beams are used. FIG. 7 (c) shows a graph when the tophat beam is used.

The tophat beam may be a beam that enables energy of the laser L to have a uniform energy density in a substantially whole laser irradiation region. For example, the tophat beam may have a flat profile in a substantial portion of the beam. As described above, the tophat beam may be generated from a Gaussian beam by using a plurality of diffractive optical elements.

When an energy density of the laser L does not reach a removal-enabling level, the energy level may not be sufficient to remove the adhesive residual material 25 at the corresponding laser irradiation point. In this case, the laser may not effectively remove the adhesive residual material 25. The removal-enabling level of laser energy may therefore be set to an energy level that enables the adhesive residual material 25 to be removed.

On the other hand, when an energy density of the laser L is excessive and corresponds to a level where the photomask M is damaged, the area where the adhesive residual material 25 is removed may be wide at the laser irradiation area as shown in FIG. 7 (a). However, because of the excessive energy, the surface of the photomask M may be damaged by the laser irradiation. For example, the photomask M may be damaged by an excessive level of laser energy during the photomask cleaning process.

In order to effectively remove the adhesive residual material 25 without damaging the photomask M, the maximum level of energy density of the laser L may be set to be below the level that damages the photomask M, but above the level effectively removing the adhesive residual material 25.

Referring to FIG. 7 (b), since an energy distribution corresponding to an energy density of the irradiated laser L has a Gaussian form, a width where the adhesive residual material 25 is removed in the laser irradiation area is narrow, making the cleaning process less efficient because the laser L removes relatively small areas of residual adhesive material, for example, per unit irradiation time.

On the other hand, a laser L having a tophat profile may be uniformly distributed throughout its irradiation area with an energy density for which an adhesive residual material is removed. Therefore, a broader area of the adhesive residual material 25 is removed by a laser irradiation, for example, per unit irradiation time, than when the area of a laser having the Gaussian profile is used. For example, the number of irradiations of a laser may be reduced, and therefore, the photomask cleaning process is more efficiently performed. Referring to FIG. 7 (a), when the Gaussian beam is used as the laser L, a maximum intensity of energy may reach a level where the photomask M is damaged by the energy, by broadening an adhesive residual material removal-enabling region of the laser profile. When the laser L having the Gaussian beam profile is repeatedly irradiated onto the photomask M, the photomask M may be damaged.

Referring to FIG. 7 (b), in a case where the Gaussian beam is used as the laser L, when a maximum intensity of energy is below the level for which the photomask M may be damaged, the area where an adhesive residual material is removed by the laser L may be very narrow. For this reason, it may take a relatively long time to remove the adhesive residual material 25.

Referring to FIG. 7 (c), when the tophat beam is used as the laser L, a maximum level of intensity of energy is located in a range where the photomask M is not damaged, and where the adhesive material is removed. The area of profile of the tophat beam where an adhesive residual material is removed is broader than a case of using the Gaussian beam. Therefore, it may take a relatively short time to remove the adhesive residual material 25 without the photomask M being damaged.

When the tophat beam is used as the laser L, a maximum intensity of energy of the tophat beam may be determined within a range of affecting removal of the adhesive residual material M without the photomask M being substantially damaged. The maximum intensity of the energy of the tophat beam may be determined depending on a material of the photomask M and a material of the adhesive 23 (see FIG. 1).

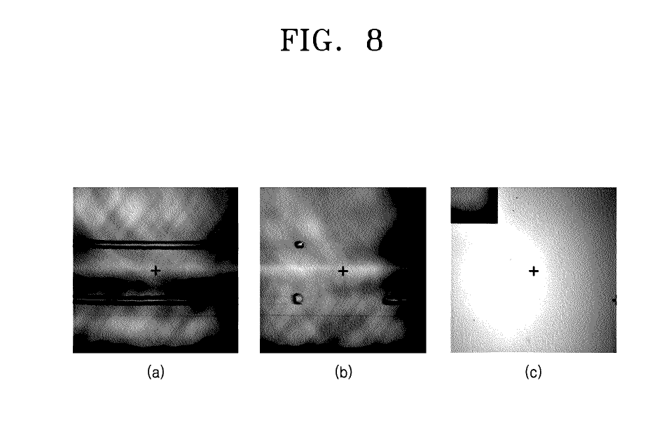

FIG. 8 depicts images showing a photomask cleaned by a photomask cleaning apparatus according to an example embodiment.

Referring to FIGS. 3 and 8, the images are images of a specimen which shows an operation result of removing the adhesive residual material 25 of the photomask M by using the photomask cleaning apparatus according to an example embodiment. In the laser L used to remove the adhesive residual material 25, a maximum intensity may be 25 mJ/cm², a frequency may be 100 Hz, a beam size may be 2 mm×2 mm, and a time taken in a one-time process may be set to 40 seconds. Quartz may be used as a material of the photomask M, and a styrene block copolymer may be used as the adhesive 23 (see FIG. 1).

Referring to FIG. 8 (a), an image shows the adhesive residual material 25 which successively remains on the photomask M in a horizontal direction. The image shows only a portion of the photomask M, and as illustrated in FIG. 2, the adhesive residual material 25 may be formed in a tetragonal shape in the second region 20 of the photomask M.

Referring to FIG. 8 (b), an image shows adhesive residual material 25 having portions that have been removed by irradiating a laser L, having the above-described conditions, onto the adhesive residual material 25. In an actual photomask cleaning process, such a process may be performed for all of the adhesive residual material 25 formed on the photomask M, thereby removing all of the adhesive residual material 25.

Referring to FIG. 8 (c), after thirty times of irradiation (1,200 sec) was performed to remove an adhesive residual material 25, the photomask M was checked whether the photomask M is damaged. For example, an image of a portion of the photomask M from which the adhesive residual material 25 has been removed may be enlarged, whereupon whether the photomask M is damaged may be checked. As seen in the image, it can be seen that even when an adhesive residual material removing process is performed tens of times, the photomask M is not damaged.

As described above, when the photomask M is cleaned by the photomask cleaning apparatus according to exemplary embodiments, by using the laser L instead of a cleaning solution, all of the adhesive residual material remaining on the photomask M may be removed without the photomask M being damaged.

While the inventive concept has been particularly shown and described with reference to example embodiments thereof, it will be understood that various changes in form and details may be made therein without departing from the spirit and scope of the following claims.

What is claimed is:

1. A method comprising:
placing a photomask on a receiver of a cleaning apparatus; and
removing adhesive residue from the photomask by irradiating laser on the adhesive residue,
wherein the irradiating laser repeatedly pauses and restarts during the removing of the adhesive residue.

2. The method of claim 1, wherein the laser irradiation pauses before an accumulated energy of the laser irradiation in the photomask reaches a level that damages the photomask, and the irradiation repeats after the photomask discharges energy absorbed thereby.

3. The method of claim 2, wherein the laser irradiation has a certain period and a certain wavelength, the certain period is shorter than a dissipation duration of the accumulated energy in the adhesive residue and is longer than a dissipation duration of the accumulated energy in the photomask.

4. The method of claim 3, wherein the certain period is 0.005 sec to 1 sec.

5. The method of claim 3, wherein the laser having the certain wavelength has an absorption rate higher in the adhesive residue than the photomask.

6. The method of claim 1, wherein the laser is a tophat beam.

7. The method of claim 6, wherein the tophat beam has a maximum intensity within a range that removes the adhesive residue without damaging the photomask.

8. The method of claim 7, wherein a time for which the maximum intensity is maintained is shorter than a time for which energy accumulation in the photomask reaches a level that damages the photomask.

9. The method of claim 1, further comprising: removing a pellicle from the photomask before placing the photomask on the receiver.

10. The method of claim 1, further comprising:
exposing a semiconductor substrate to a light using the photomask.

11. A method comprising:
removing a pellicle from a photomask, the photomask comprising a first region where a mask pattern is formed and a second region surrounding the first region;
placing the photomask on a receiver of a cleaning apparatus; and
removing pellicle adhesive residue from the photomask by irradiating laser on the adhesive residue,
wherein the laser has a tophat profile, and the irradiating laser removes the pellicle adhesive residue in the second region of the photomask.

12. The method of claim 11, wherein the irradiating laser repeatedly pauses and restarts during the removing of the adhesive residue, the irradiating laser pauses before the accumulation of energy in the photomask reaches a level that damages the photomask, and the irradiating laser restarts after the photomask discharges all of energy absorbed in the photomask.

13. The method of claim 12, wherein the laser has a frequency of 1 Hz to 200 Hz.

14. The method of claim 11, further comprising:
scanning the second region to check information about the pellicle adhesive residual material, and
controlling one or more of a period, a wavelength, an irradiation duration, number of repetitions, and a repetition interval of the laser, based on the information about the pellicle adhesive residual material.

15. The method of claim 11, further comprising:
heating the photomask before the laser is irradiated onto the pellicle adhesive residue, and cooling the photomask after the pellicle adhesive residue is removed.

16. A method, comprising:
placing a photomask on a receiver of a cleaning apparatus;
removing adhesive residue from the photomask by irradiating laser on the adhesive residue;
attaching a pellicle to the photomask; and
exposing a semiconductor substrate to a light using the photomask,
wherein the irradiating laser repeatedly pauses and restarts during the removing of the adhesive residue.

17. The method of claim 16, wherein the irradiating laser has a tophat profile.

18. The method of claim 17, wherein the irradiating laser pauses before an accumulated energy of the irradiating laser in the photomask reaches a level that damages the photomask, and the laser irradiates again after the photomask discharges energy absorbed in the photomask.

19. The method of claim 18, wherein the laser has a period shorter than a dissipation duration of the accumulated energy in the adhesive residue and longer than a dissipation duration of the accumulated energy in the photomask.

20. The method of claim 19, wherein the period of the laser is 0.005 sec to 1 sec.
